(19) United States
(12) Patent Application Publication
(10) Pub. No.: US 2010/0098855 A1
(43) Pub. Date: Apr. 22, 2010

(54) FURNACE TEMPERATURE CONTROL METHOD FOR THERMAL BUDGET BALANCE

(75) Inventors: CHENG CHE CHIANG, TAIPEI COUNTY (TW); CHEN YEN KUO, HUALIEN COUNTY (TW); YIN KUEI YU, HUALIEN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY (TW)

(21) Appl. No.: 12/433,913

(22) Filed: May 1, 2009

(30) Foreign Application Priority Data
Oct. 17, 2008 (TW) 97139925

(51) Int. Cl. C23C 16/44; C23C 16/54

(52) U.S. Cl. 427/255.28; 118/724

(57) ABSTRACT

A furnace temperature control method for thermal budget balance includes the steps of: placing a plurality of batches of wafers in the furnace; processing the wafers in the furnace via a heat deposition process; adjusting temperature in the furnace during the heat deposition process so that the temperature in the furnace has a temperature gradient; and controlling and inverting the temperature gradient so that the wafers in the furnace have the same thermal budget, whereby the electric parameters of the processed wafers tend to become uniform. Accordingly, considering the influence of the thermal budget, the present invention adjusts the temperature in the furnace and balances the thermal budget of the wafers in the furnace to avoid that the electric parameters of the processed wafers have extreme values, thereby improving the yield rate.

### BACKGROUND OF THE INVENTION

1. Field of the Invention

The present invention relates to a heat deposition process for controlling thermal balance, and more particularly to a furnace temperature control method for thermal budget balance which adjusts the temperature gradient in a furnace to so that the electric parameters of the wafers produced by the furnace tend to be uniform.

2. Description of Related Art

Please refer to FIG. 1 illustrating a conventional wafer heat deposition process in semiconductor factories which includes the steps of:
(A). firstly, placing a plurality of batches of wafers in a furnace;
(B). secondly, applying a heat deposition process to the batches of wafers; and
(C). finally, removing the batches of processed wafers from the furnace; wherein
   the temperature in the furnace is constant during the heat deposition process in step (B).

At present, semiconductor factories all process wafers via the above described heat deposition process. However, it has been found that the above described heat deposition process has some negative effects on the wafers in the furnace. The reason is that the furnace 1a used in the process is a vertical furnace. When the batches of wafers are placed in the furnace, the top wafer 2a is heated first and the bottom wafer 2a is heated last (please refer to FIG. 2A); and after the process, the bottom wafer 2a leaves the furnace 1a first and the top wafer 2a leaves the furnace 1a last (please refer to FIG. 2B). So there are different thermal budgets on the batches of wafers 2a in the furnace 1a under the influence of the above two factors.

Please refer to FIG. 3 and FIG. 4. Since the temperature in different regions in the furnace is constant, the wafers located in different regions are affected by different thermal budgets, so that the wafers processed in the same furnace have different electric parameters, which affects subsequent processes and finally causes the decrease of production yield rate.

Accordingly, the conventional wafer heat deposition process has the shortcomings as follows:

1. According to an electric test conducted after the process (FIG. 4), the wafers treated in the same furnace have different electric parameters;

2. The differences in electric parameters of the wafers affect subsequent processes and cause the decrease of yield rate.

Hence, the inventors of the present invention believe that the shortcomings described above can be remedied and finally suggest the present invention which is of a reasonable design and is an effective improvement based on deep research and thought.

### SUMMARY OF THE INVENTION

A main object of the present invention is to provide a furnace temperature control method for thermal budget balance which adjusts temperature in a furnace based on a simple concept to change the temperature gradient so that the electric parameters of the processed wafers tend to be uniform, thereby avoiding extreme variation of the electric parameters which causes a decrease in yield rate.

To achieve the above-mentioned object, a furnace temperature control method for thermal budget balance in accordance with the present invention is provided. The method includes the steps of: providing a furnace and placing a plurality of batches of wafers in the furnace; inputting process gas into the furnace; processing the wafers in the furnace via a heat deposition process; adjusting temperature at different positions in the furnace so that the temperature in the furnace has a temperature gradient; and further adjusting the temperature in the furnace to invert the temperature gradient and balance the thermal budget on the batches of wafers so that the electric parameters of the processed wafers tend to be uniform.

The present invention further provides a furnace temperature control method for thermal budget balance which includes the steps of: processing a plurality of batches of wafers via a heat deposition process; adjusting temperature in the heat deposition process to have a temperature gradient; and adjusting the temperature in the heat deposition process again such that the temperature gradient has a tendency to balance the thermal budget, thereby rendering the electric parameters of the processed wafers more uniform.

The efficacy of the furnace temperature control method for thermal budget balance of the present invention is as follows:

1. The furnace temperature control method for thermal budget balance of the present invention can ensure that the processed wafers have the electric parameters tending to be uniform to solve the problem that some processed wafers have very extreme electric parameters.

2. The furnace temperature control method for thermal budget balance of the present invention can ensure that the wafers have uniform electrical characteristics.

3. The furnace temperature control method for thermal budget balance of the present invention adjusts the temperature in the furnace based on temperature inversion to solve the problem that some processed wafers produced in the same furnace have very extreme electric parameters and ensure that the electric parameters of the processed wafers are even and uniform.

4. The furnace temperature control method for thermal budget balance of the present invention can be used in existing semi-conductor factories and executed in conventional furnaces by a simply control method, so the present invention won't affect the process.

To further understand advantages and spirits of the present invention, please refer to the following detailed description and drawings related the present invention.

### BRIEF DESCRIPTION OF THE DRAWINGS

FIG. 1 is a flow chart of a conventional wafer heat deposition process in semiconductor factories;

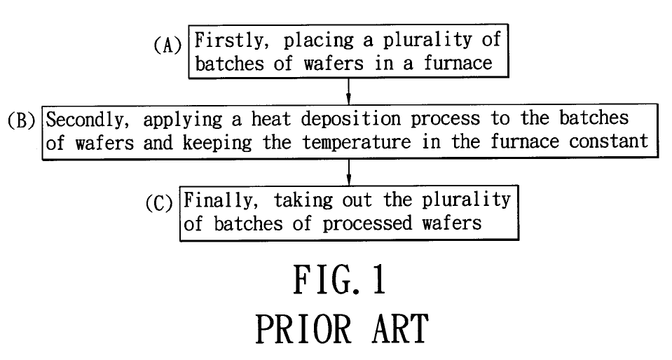

FIG. 2A is a flow schematic view of placing wafers in a furnace;

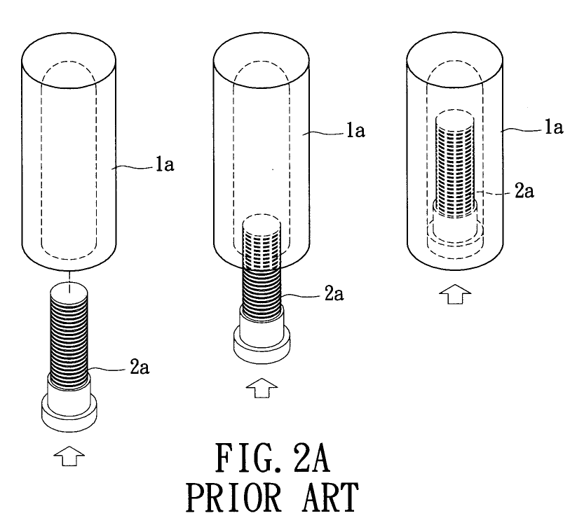

FIG. 2B is a flow schematic view of taking the wafers out of the furnace;

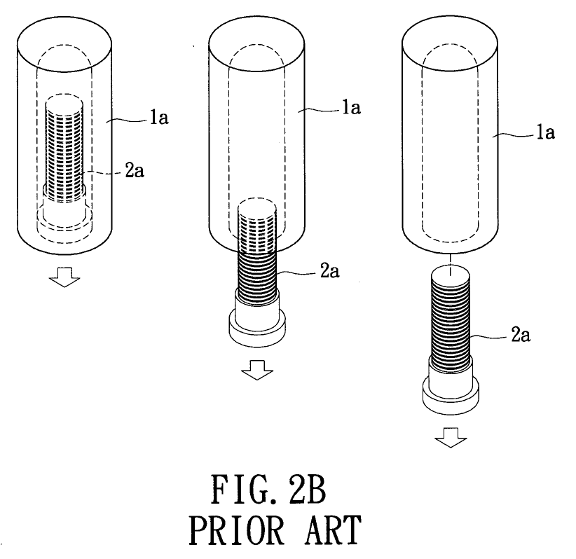

FIG. 3 is a relation graph of furnace temperature and process time of the conventional wafer heat deposition process in semiconductor factories;

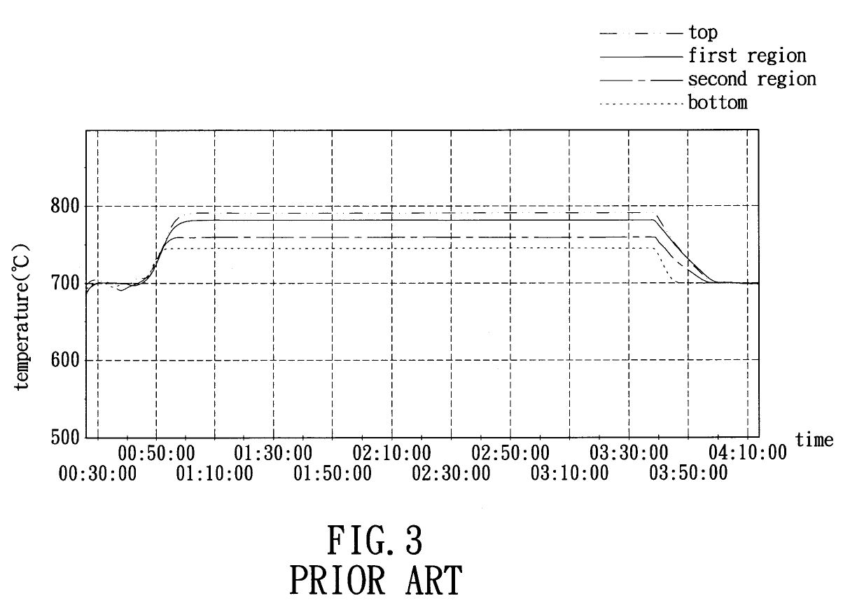

FIG. 4 is a relation graph of wafer positions and electric parameters of the conventional wafer heat deposition process in semiconductor factories;

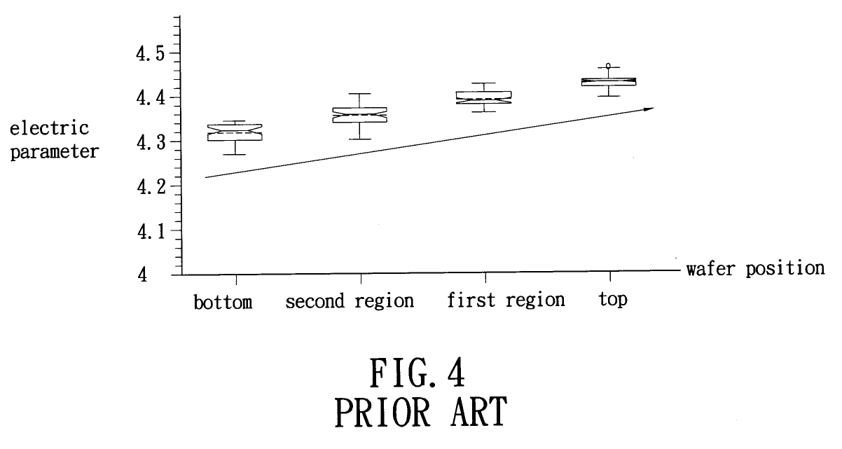

FIG. 5 is a flow chart of a furnace temperature control method for thermal budget balance of the present invention;

FIG. 6 is a structural schematic view of the furnace temperature control method for thermal budget balance of the present invention;

FIG. 7 is a relation graph of furnace temperature and process time of the furnace temperature control method for thermal budget balance of the present invention; and

FIG. 8 is a relation graph of wafer positions and electric parameters of the furnace temperature control method for thermal budget balance of the present invention.

### DETAILED DESCRIPTION OF THE PREFERRED EMBODIMENTS

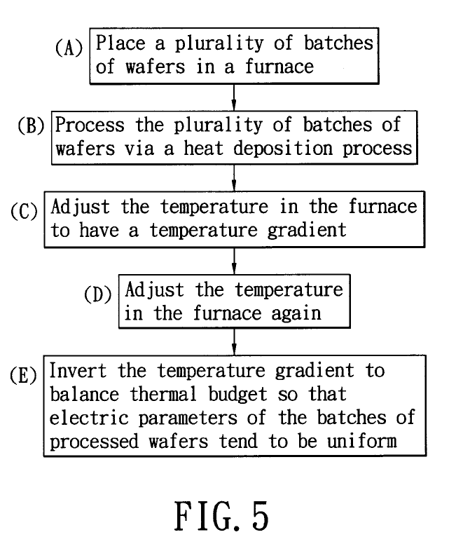

Please refer to FIG. 5 illustrating a furnace temperature control method for thermal budget balance in accordance with the present invention. The method includes the steps of:

(A). placing a plurality of batches of wafers in a furnace;

(B). processing the batches of wafers via a heat deposition process;

(C). adjusting the temperature in the furnace to have a temperature gradient;

(D). adjusting the temperature in the furnace again;

(E). inverting the temperature gradient to balance the thermal budget so that electric parameters of the batches of processed wafers tend to be uniform.

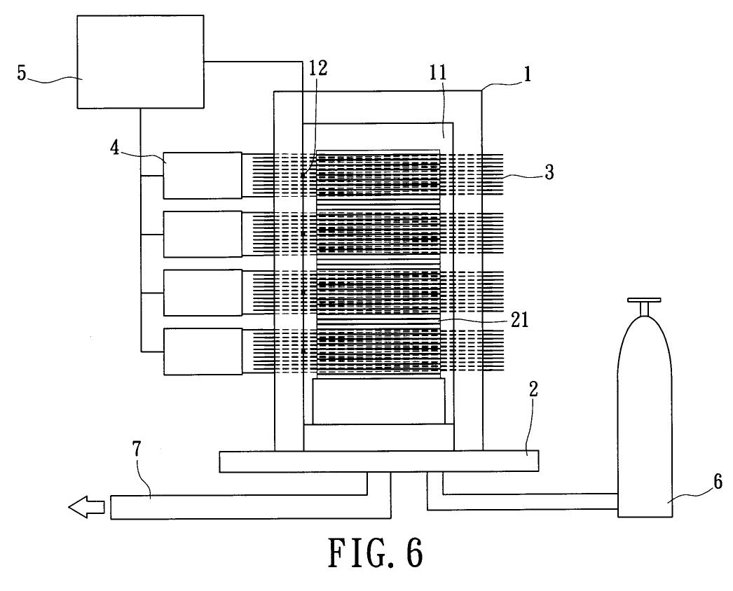

For helping those skilled in the art understand and implement the present invention, the method of the present invention will be described in detail herein. Please refer to FIG. 6 illustrating a furnace used in the furnace temperature control method for thermal budget balance of the present invention. The furnace is a vertical high temperature furnace which includes a furnace body 1, a loading base 2, a plurality of heating coils 3, a plurality of power supplies 4, a temperature controller 5, a gas supply 6 and an exhaust pipeline 7. The furnace body 1 is combined with the loading base 2, the heating coils 3 surround the outer wall of the furnace body 1, and the heating coils 3 are connected with the plurality of power supplies 4 so that the power supplies 4 can respectively control the heating coils 3 to heat the furnace body 1.

The furnace body 1 has a chamber 11 which is used as a machining space. A plurality of thermal measurement devices 12 is mounted in the chamber 11, corresponding to the heating coils 3, to measure temperature in the chamber 11. The thermal measurement device 12 is further connected with the temperature controller 5 which is used for receiving the data measured by the thermal measurement device 12. The temperature controller 5 is further connected with the plurality of power supplies 4. The temperature controller 5 controls the power supplies 4 according to the measured data and the power supplies 4 supply power to the heating coils 3 for determining the temperature in the chamber 11. In the embodiment, the thermal measurement devices 12 are thermocouples.

The loading base 2 is used for loading the plurality of batches of wafers 21 and is combined with the furnace body 1 so that the batches of wafers 21 are received in the chamber 11 to be processed.

The gas supply 6 is connected with the chamber 11 of the furnace body 1 to input process gas into the chamber 11. The process gas reacts with the batches of wafers 21. The exhaust pipeline 7 is connected with the chamber 11 to exhaust the process gas in the chamber 11 after the process.

During furnace process, the batches of wafers 21 are placed in the chamber 11 and the gas supply 6 inputs the process gas into the chamber 11 to execute the heat deposition process. The power supplies 4 respectively supply power to the heating coils 3 and then the heating coils 3 heat the furnace body 1 so that the temperature of the chamber 11 of the furnace body 1 increases, and the heat deposition process starts. The heat deposition process may be Low Pressure Chemical Vapor Deposition (LPCVD) or Atmospheric Pressure Chemical Vapor Deposition (APCVD).

Further control the temperature controller 5 to adjust heating levels of the power supplies 4 so that the temperature of the chamber 11 has a temperature gradient, that is, there is a temperature difference between the temperature at the top and the temperature at the bottom of the furnace, resulting in a temperature gradient.

Because the temperature gradient has only one direction, the batches of wafers 21 located at different positions in the chamber 11 can easily acquire different thermal budgets, which results in the batches of processed wafers 21 having different electric parameters, that is, some wafers 21 having very extreme electric parameters.

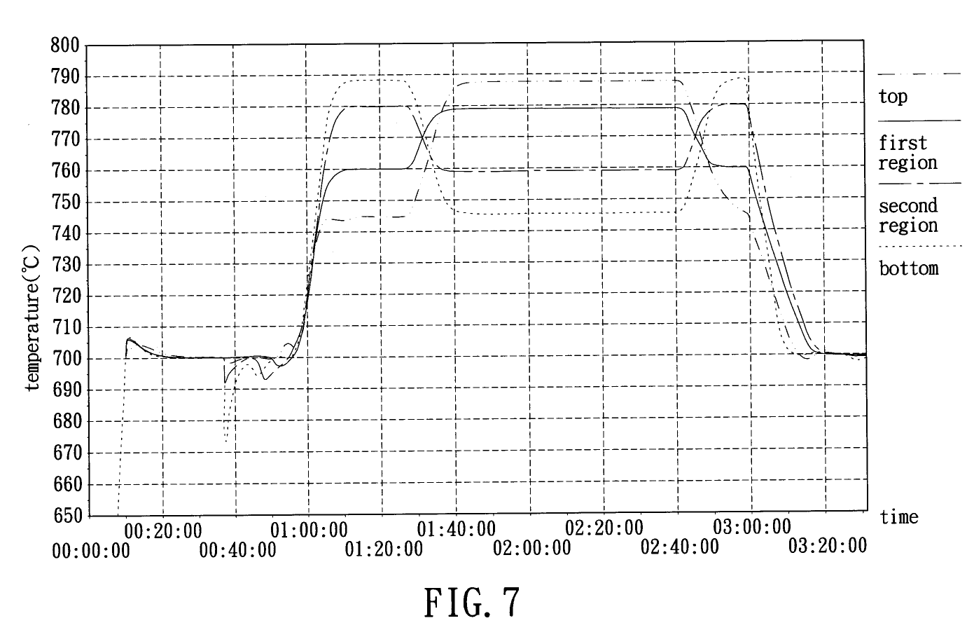

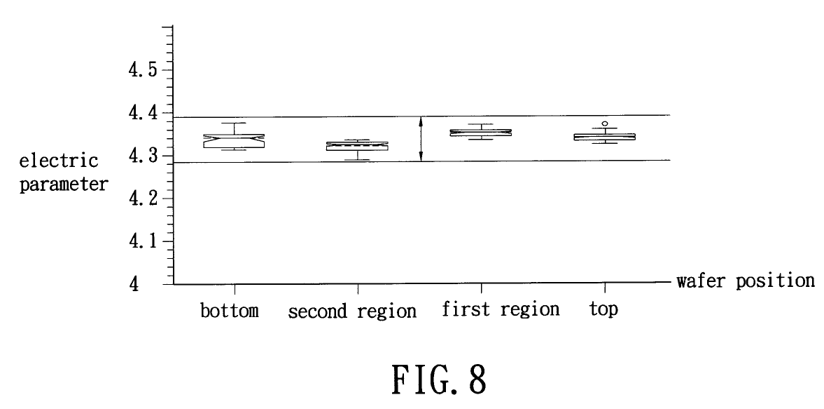

Accordingly, for keeping a uniform thermal budget on the batches of wafers 21 located at different positions in the chamber 11, the controller adjusts the power supplies 4 again so that the furnace top temperature and the furnace bottom temperature are inverted, that is, the temperature at the top of the furnace is adjusted to the prior temperature at the bottom of the furnace and the temperature at the bottom of the furnace is adjusted to the prior temperature at the top of the furnace. Thereby the original temperature gradient is adjusted to have the opposite direction (as shown in FIG. 7). Thereby, the thermal budget can be balanced and the batches of wafers 21 placed in the chamber 11 can have the same thermal budget, so that the electric parameters of the batches of processed wafers 21 tend to be uniform (as shown in FIG. 8).

Please refer to FIG. 7 illustrating a relation graph of furnace temperature and process time of the furnace temperature control method for thermal budget balance of the present invention, wherein the horizontal axis stands for time and the longitudinal axis stands for temperature. The method of the present invention can adjust the temperature of the chamber 11 such as to invert the temperature at different regions of the chamber 11 so that the temperature gradient in the furnace changes to adjust the electric parameters of the wafer 21. Finally, please refer to FIG. 8 in which the horizontal axis stands for wafer positions and the longitudinal axis stands for electric parameters. After the process, inverting of the temperature can ensure that the wafers located at different positions of the chamber 11 have the same thermal budget so that the electric parameters of the processed wafers 21 tend to be uniform, which benefits the subsequent processes for the batches of wafers 21 and finally improves the yield rate.

Consequently, the furnace temperature control method for thermal budget balance of the present invention has the advantages as follows:

1. The present invention applies the simple control method in existing semi-conductor factories, and does not require additional equipment and can be executed in conventional high temperature furnaces, so the present invention won't affect the process and increase the costs.

2. The wafers produced in the furnace temperature control method for thermal budget balance of the present invention have the electric parameters tending to be uniform.

3. The furnace temperature control method for thermal budget balance of the present invention can ensure that the processed wafers have the electric parameters tending to be uniform to solve the problem that some processed wafers have very extreme electric parameters.

4. The present invention adjusts the temperature in the furnace based on temperature inversion to solve the problem that some processed wafers have very extreme electric parameters and to ensure that the electric parameters of the processed wafers are even and uniform.

What are disclosed above are only the specification and the drawings of the preferred embodiment of the present invention and it is therefore not intended that the present invention be limited to the particular embodiments disclosed. It will be understood by those skilled in the art that various equivalent changes may be made depending on the specification and the drawings of the present invention without departing from the scope of the present invention.

What is claimed is:

1. A furnace temperature control method for thermal budget balance, comprising the steps of:
providing a furnace having a top and a bottom and placing a plurality of batches of wafers in the furnace;
inputting process gas into the furnace;
processing the wafers in the furnace via a heat deposition process;
adjusting the temperature at different positions in the furnace so that the temperature in the furnace has a temperature gradient; and
adjusting the temperature in the furnace to invert the temperature gradient and balance the thermal budget of the batches of wafers so that the electric parameters of the processed wafers tend to be uniform.

2. The method as in claim 1, wherein the heat deposition process is Low Pressure Chemical Vapor Deposition or Atmospheric Pressure Chemical Vapor Deposition.

3. The method as in claim 1, wherein the furnace has a plurality of heating regions which is formed by a plurality of heating coils surrounding the furnace.

4. The method as in claim 3, wherein the heating coils respectively heat the furnace so that the temperature at different positions in the furnace has different values.

5. The method as in claim 3, wherein the temperature gradient is inverted by the heating regions respectively heating the furnace and adjusting the temperature at different positions in the furnace so that the temperature gradient acquires an opposite direction.

6. The method as in claim 1, wherein the temperature gradient in the furnace is produced by the difference between the temperature at the top of the furnace and the temperature at the bottom of the furnace.

7. The method as in claim 6, wherein the temperature gradient is inverted by adjusting the temperatures at the top and the bottom of the furnace so that the temperature at the top of the furnace assumes the value of the original temperature at the bottom of the furnace and the temperature at the bottom of the furnace assumes the value of the original temperature at the top of the furnace.

8. The method as in claim 6, wherein the thermal budget of the plurality of batches of wafers is balanced by inverting the temperature gradient so that a wafer at the top of the furnace and a wafer at the bottom of the furnace have the same thermal budget and the electric parameters of the processed wafers tend to be uniform.

9. A furnace used in the method as in claim 1, which is a vertical high temperature furnace, comprising:
a furnace body;
a loading base, loaded with a plurality of batches of wafers and combined with the furnace body; and
a plurality of heating coils, respectively surrounding the furnace body and heating the furnace body so that the temperature in the furnace body has a gradient.

10. The furnace as in claim 9, wherein the furnace body has a chamber formed therein for receiving the plurality of batches of wafers and the batches of wafers are processed in the furnace via a heat deposition process.

11. The furnace as in claim 9, wherein the plurality of heating coils is connected with a plurality of power supplies and the power supplies respectively supply power to the heating coils so that the heating coils heat the furnace body.

12. The furnace as in claim 11, wherein a plurality of thermal measurement devices are mounted in the furnace body, respectively corresponding to the heating coils, to measure the temperature at different positions in the chamber.

13. The furnace as in claim 12, further comprising a temperature controller which is connected with the thermal measurement devices in the furnace body and the power supplies and adjusts the power supplies according to the temperature measured by the thermal measurement devices to determine the temperature at different positions in the furnace body.

14. The furnace as in claim 9, wherein the furnace body further is connected with a gas supply for inputting process gas into the furnace body and an exhaust pipeline for exhausting the process gas after the process.

15. A furnace temperature control method for thermal budget balance, comprising the steps of:
processing a plurality of batches of wafers via a heat deposition process;
adjusting the temperature in the heat deposition process to produce a temperature gradient; and
adjusting the temperature in the heat deposition process again so that the temperature gradient has an opposite direction in order to balance the thermal budget received by the wafers, thereby rendering the electric parameters of the processed wafers approximately uniform.

16. The method as in claim 15, wherein the plurality of batches of wafers is placed in a vertical high temperature furnace to be processed in the heat deposition process.

17. The method as in claim 15, wherein the heat deposition process is Low Pressure Chemical Vapor Deposition or Atmospheric Pressure Chemical Vapor Deposition.

18. The method as in claim 15, wherein the opposite direction of the temperature gradient is caused by inverting the temperature gradient.

19. The method as in claim 18, wherein balancing the thermal budget is achieved by inverting the temperature gradient so that a wafer at the top of the furnace and a wafer at the bottom of the furnace have the same thermal budget, rendering the electric parameters of the processed wafers approximately uniform.
